(19) United States
(12) Patent Application Publication
(10) Pub. No.: US 2016/0247531 A1
(43) Pub. Date: Aug. 25, 2016

(54) MAGNETIC STORAGE DISC BASED ON EXCHANGE-BIAS

(71) Applicant: University of York, York (GB)

(72) Inventors: Kevin O'Grady, Stamford Bridge (GB); Gonzalo Vallejo Fernandez, York (GB)

(21) Appl. No.: 14/938,139

(22) Filed: Nov. 11, 2015

Related U.S. Application Data
(63) Continuation-in-part of application No. 14/628,911, filed on Feb. 23, 2015.

(51) Int. Cl. G11B 5/73; G11B 5/851; C23C 14/08; C23C 14/34; C23C 14/16; G11B 5/667; G11B 5/65

(52) U.S. Cl. CPC G11B 5/7325; G11B 5/667; G11B 5/851; G11B 5/656; G11B 5/732; C23C 14/34; C23C 14/165; C23C 14/087; C23C 14/085; G11B 2005/0021

(57) ABSTRACT

There is provided a magnetic storage disc comprising a heat-assisted magnetic recording structure comprising an adjoining ferromagnetic sputtered layer and antiferromagnetic sputtered layer magnetically coupled to each other by a magnetic exchange interaction giving rise to exchange bias, wherein the anisotropy axis of the antiferromagnetic sputtered layer is configured to be perpendicular to at least one seed layer disposed between the antiferromagnetic sputtered layer and a supporting substrate. A magnetically soft layer is disposed between the antiferromagnetic sputtered layer and the at least one seed layer. A method of forming a magnetic recording disc is also provided.

### RELATED APPLICATION

This application is a continuation-in-part of, and claims priority under 35 U.S.C. §120 to, U.S. patent application Ser. No. 14/628,911, which was filed on Feb. 23, 2015, is entitled “Magnetic Storage Disc Based on Exchange-Bias,” and the complete disclosure of which is hereby incorporated by reference.

### FIELD

The present invention relates to a magnetic storage disc, such as a heat-assisted magnetic recording disc, based on exchange bias interaction between a ferromagnetic thin film and an anti-ferromagnetic thin film.

### BACKGROUND

When storing data in media such as hard discs, superposed layers of magnetic materials are used to create magnetic structures for recording information. New information needs to be written to the magnetic structure and existing information read from the magnetic structure. The amount of data that can be stored is limited by the size of the magnetic grains within the magnetic structures. If the magnetic anisotropy of the magnetic materials is increased, the amount of data that can be stored increases. However, if the magnetic anisotropy is too high, then it can be very difficult to write new information to the magnetic structure.

Heat assisted magnetic recording (HAMR) has been proposed where a data storage layer comprises a ferromagnetic film of a material whose anisotropy is based on its crystalline structure. It is known that such anisotropy exhibits a significant temperature dependence whereby it and in consequence the coercivity of the material reduces at an elevated temperature. The materials proposed for use in such a system are principally the alloy Iron Platinum (FePt) or Cobalt Platinum (CoPt) having a high temperature coefficient of a magnetocrystalline anisotropy constant.

Data is written to a HAMR system by a heat-assisted process generated either via a laser built into a write head or via a separate coil generating microwave frequency radiation such that the decrease in the anisotropy causes a decrease in the coercivity of the material into the range where a conventional write head is able to switch the material, hence writing the bit. On subsequent cooling of the recording layer back to near room temperature, the anisotropy, and hence the coercivity, increases thereby giving thermally stable bits of information at very high recording densities. However difficulties have been encountered in implementing such systems.

### SUMMARY

Magnetic storage discs with a heat-assisted magnetic recording structure and a method of forming such a magnetic recording disc are disclosed herein. Magnetic storage discs according to the present disclosure include those with a heat-assisted magnetic recording structure formed from adjoining ferromagnetic and anti-ferromagnetic sputtered layers magnetically coupled to each other by a magnetic exchange interaction giving rise to exchange bias. Magnetic storage discs according to the present disclosure have at least one seed layer disposed between the anti-ferromagnetic sputtered layer and a substrate.

### BRIEF DESCRIPTION OF THE DRAWINGS

FIG. 1 is a section through a magnetic storage device;

FIG. 2 shows the magnetisation curve with exchange bias;

FIG. 3 shows a section through a first example of multi-layered magnetic storage structure;

FIG. 4 shows a section through a second example of a multi-layered magnetic storage device; and

FIG. 5 shows a graph of exchange bias interaction against varying thickness of an antiferromagnetic layer for the example shown in FIG. 4.

### DESCRIPTION

In accordance with one aspect of the present disclosure there is provided a magnetic storage disc comprising a heat-assisted magnetic recording structure comprising an adjoining ferromagnetic sputtered layer and antiferromagnetic sputtered layer magnetically coupled to each other by a magnetic exchange interaction giving rise to exchange bias when the film is cooled from an elevated temperature in a field, wherein the anisotropy axis of the antiferromagnetic sputtered layer is configured to be perpendicular to at least one seed layer disposed between the antiferromagnetic sputtered layer and a substrate. By having a film layer which grows naturally with an anisotropy axis perpendicular to the plane of the seed layer, there is no need to anneal the antiferromagnetic layer to obtain anisotropy through a phase transformation.

An intermediate layer comprising a soft magnetic material may be disposed between the antiferromagnetic sputtered layer and the at least one seed layer. This is particularly preferred for perpendicular magnetic recording systems. The sputtered layers will preferably be thin films.

The seed layer may comprise a cubic structure and may be a non-magnetic metal with a cubic structure. The at least one seed layer may comprise a face-centred cubic structure, with the (111) crystal plane lying perpendicular to the plane of the layer and to the contact surface between the substrate and the at least one seed layer. Such a seed layer is selected to ensure the sputtered antiferromagnetic layer deposits with its anisotropy axis perpendicular to the plane of the seed layer. The at least one seed layer may comprise Ru, Cu, Pt, or NiCr.

The substrate is typically in the form of a planar disc.

The ferromagnetic sputtered layer may comprise a CoPt alloy which, where desired, may contain Cr and other elements such as B, to provide grain size control. Alternatively or in addition, the ferromagnetic sputtered layer may comprise a multilayer system exhibiting perpendicular anisotropy, such as a multilayer superlattice structure of (Co/Pt)ₙ or (Co/Pd)ₙ when the value of n is adjusted to give the desired coercivity. The ferromagnetic sputtered layer may be co-sputtered with insulating materials such as SiO₂ to provide exchange decoupling between grains within the ferromagnetic material.

The antiferromagnetic sputtered layer may comprise IrMn, or GaMn, or AuMn, or FeMn, or PtMn, or CoO coupled to a Co alloy, or NiCoO coupled to CoNi or Co or Ni, or NiO, or CoNi or a Heusler alloy such as Ni₂MnAl. Preferably the sputtered layer has a thickness of between 5 to 20 nm.

Desirably the antiferromagnetic sputtered layer is configured to have its direction of anisotropy perpendicular to the plane in which the antiferromagnetic sputtered layer is deposited, and preferably has an anisotropy constant of at least 5×10⁶ ergs/cc.

The exchange bias field is preferably configured to be between 100 Oe to 10 kOe.

In accordance with a further aspect of the present disclosure, there is provided a method of forming a magnetic recording disc, the method comprising configuring at least one seed layer formed on a substrate so that antiferromagnetic material sputtered onto the seed layer aligns with its anisotropy axis perpendicular to the at least one seed layer, depositing an antiferromagnetic layer onto the at least one seed layer by sputtering, depositing a ferromagnetic layer onto the antiferromagnetic layer by sputtering, and magnetically coupling the ferromagnetic and antiferromagnetic layers together by a magnetic exchange interaction giving rise to exchange bias on field cooling from an elevated temperature.

The method may further comprise configuring an exchange bias field between the ferromagnetic layer and the antiferromagnetic layer to be between 100 Oe to 5 kOe.

An intermediate layer comprising a soft magnetic material may be disposed between the antiferromagnetic layer and the at least one seed layer, which is of particular advantage for a perpendicular magnetic recording system.

The antiferromagnetic layer may have an anisotropy constant of at least 5×10⁶ ergs/cc.

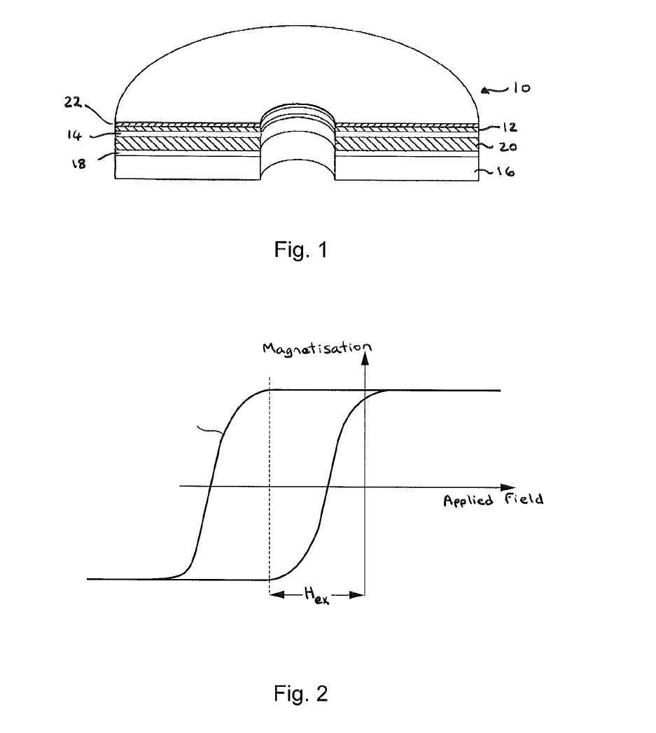

FIG. 1 shows a section through an exemplary magnetic data storage disc 10 having adjoining exchange-bias coupled ferromagnetic (F) 12 and antiferromagnetic (AF) 14 layers. Disc 10 comprises substrate 16, on which at least one seed layer 18 approximately 5 nm thick is sputtered. If desired, double seed layers can be used, for example two adjacent 8 nm and 10 nm seed layers of Cu sputtered at a process pressure of 3 mTorr and 30 mTorr respectively so as to create a void structure. The substrate is typically made of aluminium, ceramic glass, amorphous glass, or NiP coated AlMg. The seed layer is typically a non-magnetic metal with a cubic or hexagonal structure such as NiCr, Ru, Pt or Cu, and desirably a face-centred cubic structure with (111) plane parallel to the surface between substrate 16 and the magnetic layers. There needs to be a lattice match between the (111) atomic spacing of the AF layer and the lattice parameter of the seed material. This ensures the growth of the (111) planes of the sputtered AF is set perpendicular to the substrate surface.

A magnetically soft underlayer 20 being a high magnetic moment alloy, such as FeZr, is sputtered onto seed layer 18 to help focus a read/write head onto the disc. Typically layer 20 has a thickness of between 50 to 1000 nm and may be made of any suitable material such as CoFe, CoZrNb, NiFe, FeCoB, FeAlN, or FeAlSi. Layer 20 is required where a perpendicular magnetic recording system is adopted but can be omitted for longitudinal magnetic recording systems.

The magnetic storage region of disc 10 is formed by sputtered thin film layers 12 and 14. The AF is selected to have an anisotropic phase in the crystal structure it forms during sputtering. AF layer 14 is sputtered onto underlayer 20, with its anisotropy direction set perpendicular to its plane of deposition and so perpendicular to the plane of substrate 16. Typically layer 14 is formed from IrMn of a thickness 5 to 10 nm although other AF's can be used instead, such as PtMn, FeMn, GaMn₂, AuMn₂, CoO coupled to Co alloy, NiCoO coupled to CoNi or Co or Ni, NiO, CoNi or a Heusler alloy such as Ni₂MnAl. The advantages of using IrMn and similar materials in sputtered form are that they require no annealing to induce a phase transformation to provide an adequate anisotropy. Sputtered IrMn is deposited onto a planar substrate surface as an fcc (face-centred cubic) structure with its anisotropy axis orientated perpendicular to the plane of the substrate. The spin structures of the individual atoms will depend on the precise composition and the deposition conditions of the sputtered AF layer. The antiferromagnetic anisotropy constant K_{AF} and the Néel temperature T_{N} can be controlled by composition.

F layer 12 is sputtered onto AF layer 14 and is typically a Cobalt alloy, such as CoPt, of approximately 10 nm thickness. F layer 12 can be formed of a plurality of adjacent F thin films. Typically the F material has a high anisotropy with suitable materials including FePt, CoPtCr, CoPd, CoPt. The F layer can be a multi-layer structure if necessary, for example a Co/Pt multilayer where the Co thickness has between 0.5 nm and 0.8 nm and more preferably is 0.6 nm and the Pt thickness lies between 1.2 nm and 2.0 nm, and more preferably is 1.6 nm.

Table 1 below illustrates suitable ferromagnetic alloys and their compositions.

TABLE 1
Composition of Alloys

| | Preferred Composition | Composition Range |
|---|---|---|
| Alloy | (at %) | (at %) |
| FePt | 50:50 | None |
| CoCrPt | 19:10:71 | None |
| CoCrPtB | 60:20:12:8 | None |
| PtMn | 25:75 | 20:80-30:70 |
| FeMn | 50:50 | 40:60-60:40 |
| CoFe | 40:60 | 85:15-15:85 |
| NiFe | 80:20 | 90:10-45:55 |
| CoZrNb | 90:6:4 | 90:5:4-90:7:5 |
| GaMn | 20:80 | 15:85-30:70 |
| AuMn | 35:65 | 30:70-40:60 |
| IrMn | 25:75 | 20:80-30:70 |

Typically the F material will be co-sputtered with SiO₂ or any other insulating material to provide exchange decoupling between individual grains within the layer and thus F layer 12 can be CoCrPt—SiO₂ and in particular a double film of 10 nm and 20 nm thick CoCrPt—SiO₂.

The layers 20, 14, 12 are sputtered in turn so as to provide for ease of manufacture and by selecting the anisotropy axis of AF layer 14 to be orientated perpendicular to disc substrate 16, an increased anisotropy constant K_{AF} of above 5×10⁶ ergs/cc is achieved. If desired, an additional seed layer can be disposed between underlayer 20 and AF layer 14.

Generally, a protective coating layer 22 is formed on top of layer 12 to protect the magnetic surfaces.

When sputtering, the AF or F material is used as a sputter target. An ionised plasma of gas, such as Argon, is created between electrodes and accelerated under an electrical bias towards the sputter target. The ionised plasma causes small clumps of target atoms to be ejected from the sputter target and deposited on the substrate to form a uniform continuous layer. The general principles behind sputtering are well-known in the art and a guide to sputtering is set out in Vacuum Technology, Thin Films and Sputtering: An Introduction. Stuart R V, Minneapolis: Academic Press, 1983. 0-12-674780-6.

To induce an exchange bias interaction, disc 10 is heated to a temperature as high as possible, and ideally greater than the Néel temperature of the AF, a magnetic field applied and cooling undertaken with the magnetic field in place. This results in setting of an exchange bias interaction between the F and AF layers 12, 14 as shown in FIG. 2 where it can be seen that the hysteresis loop of the F layer is shifted from the origin by exchange bias field Hₑₓ which is in the region of 100 Oe to 5 kOe. Hₑₓ is reduced for increasing thickness of the F layer 12. The exchange bias interaction has produced an enhanced and temperature dependent coercivity.

By using exchange bias, the centre of the magnetic hysteresis loop is offset from zero by Hₑₓ, the exchange bias field, so ensuring the alignment of domains or grains in the FM layer cannot by altered by stray magnetic fields.

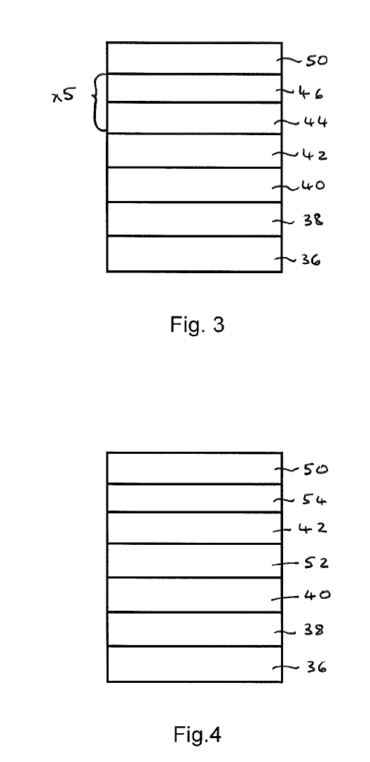

FIG. 3 shows an example of a multi-layered structure for a magnetic storage disc. Silicon substrate 36 has a number of thin film layers sputtered onto it, these being in order a 5 nm thick Ta layer 38, a seed layer 40 formed from one of Cu, Ru, Pt or NiCr, AF material 42 in the form of 10 nm thick IrMn, F material in the form of five repeat units 44, 46 of Co/Pt multi-layers, of which only one pair is shown, and an uppermost 5 nm thick Ta layer 50. The Ta layers 38, 50 are to prevent oxidation and do not alter the magnetic characteristics of the other layers. For the Co/Pt multi-layers, a 0.6 nm thickness of Co 44 is sputtered first and then a 1.6 nm thickness of Pt 46. This is repeated until these pairs of layers are replicated five times.

The multi-layered structure was heated to as high a temperature as possible, a magnetic field of 20 kOe applied perpendicular to the deposition plane of the layers and cooling to 398K undertaken with the field in place to set an exchange bias interaction between the F and AF layers.

For a seed layer of Cu, an exchange bias of 112 Oe was measured, with an Ru seed layer giving rise to an exchange bias of around 40 Oe and for NiCr, around 18 Oe.

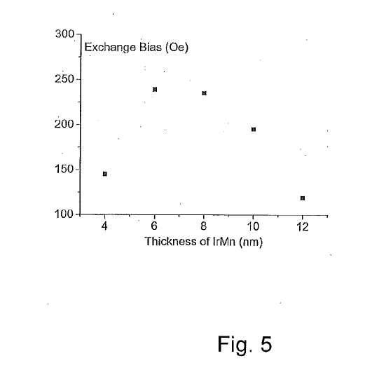

FIG. 4 shows an example of a multi-layered structure having a Pt seed layer and an intermediate layer of Co disposed between the AF material layer and the seed layer. In this example, Silicon substrate 36 bears a number of sputtered thin film layers, these being a 5 nm thick Ta layer 38, a 5 nm thick seed layer 40 formed from Pt, an intermediate layer 52 formed from a two atom thick layer of Co being 0.8 nm thick, AF material 42 in the form of IrMn with its anisotropy axis oriented perpendicular to substrate 36, F material 54 in the form of CoCrPt—SiO₂ of thickness 2 to 10 nm and an uppermost protective Ta layer 50 of thickness 5 nm. An exchange bias interaction was induced between the AF material and F material as discussed above and the exchange bias interaction measured at room temperature for a CoCrPt—SiO₂ layer of 4 nm thickness as compared to thicknesses of IrMn between 4 to 12 nm as shown in FIG. 5. It can be seen that an exchange bias of around 240 Oe was achieved for an IrMn layer of 6 nm thickness.

1. A magnetic storage disc comprising a heat-assisted magnetic recording structure comprising an adjoining ferromagnetic sputtered layer and an antiferromagnetic sputtered layer magnetically coupled to each other by a magnetic exchange interaction giving rise to exchange bias, wherein the anisotropy axis of the antiferromagnetic sputtered layer is configured to be perpendicular to at least one seed layer disposed between the antiferromagnetic sputtered layer and a supporting substrate.

2. The magnetic storage disc according to claim 1, wherein an intermediate layer comprising a soft magnetic material is disposed between the antiferromagnetic sputtered layer and the at least one seed layer.

3. The magnetic storage disc according to claim 2, wherein the antiferromagnetic sputtered layer is configured to have its direction of anisotropy perpendicular to the plane in which the antiferromagnetic sputtered layer is deposited.

4. The magnetic storage disc according to claim 2, wherein the intermediate layer is Co.

5. The magnetic storage disc according to claim 4, wherein the Co intermediate layer is two Co atoms thick.

6. The magnetic storage disc according to claim 1, wherein the antiferromagnetic sputtered layer is configured to have its direction of anisotropy perpendicular to the plane in which the antiferromagnetic sputtered layer is deposited.

7. The magnetic storage disc according to claim 1, wherein the sputtered layers are thin films.

8. The magnetic storage disc according to claim 1, wherein the at least one seed layer comprises a cubic structure.

9. The magnetic storage disc according to claim 8, wherein the at least one seed layer comprises a face-centred cubic structure with the (111) crystal plane parallel to the plane of the at least one seed layer.

10. The magnetic storage disc according to claim 1, wherein the ferromagnetic sputtered layer comprises a CoPt alloy and/or a (Co/Pt)ₙ multilayer.

11. The magnetic storage disc according to claim 1, wherein the antiferromagnetic sputtered layer comprises IrMn, or GaMn, or AuMn, or FeMn, or PtMn, or GaMn₂, or AuMn₂, or CoO coupled to Co, or NiCoO coupled to CoNi or Co or Ni, or NiO or CoNi or a Heusler alloy.

12. The magnetic storage disc according to claim 1, wherein the antiferromagnetic sputtered layer has a thickness of between 5 to 20 nm.

13. The magnetic storage disc according to claim 1, wherein the at least one seed layer comprises Ru, or Cu, PT, or NiCr.

14. The magnetic storage disc according to claim 1, wherein the exchange bias is between 100 Oe to 10 kOe.

15. The magnetic storage disc according to claim 1, wherein the antiferromagnetic sputtered layer has an anisotropy constant of at least 5×10⁶ ergs/cc.

16. A method of forming a magnetic recording disc, the method comprising configuring at least one seed layer formed on a substrate so that antiferromagnetic material sputtered onto the seed layer aligns with its anisotropy axis perpendicular to the at least one seed layer, depositing an antiferromagnetic layer onto the at least one seed layer by sputtering, depositing a ferromagnetic layer onto the antiferromagnetic layer by sputtering, and magnetically coupling the ferromagnetic and antiferromagnetic layers together by a magnetic exchange interaction giving rise to exchange bias.

17. The method of forming a magnetic recording disc according to claim 16, further comprising configuring an exchange bias field between the ferromagnetic layer and the antiferromagnetic layer to be between 100 Oe to 10 kOe.

18. The method of forming a magnetic recording disc according to claim 16, wherein an intermediate layer comprising a soft magnetic material is disposed between the antiferromagnetic layer and the at least one seed layer.
